(19) United States
(12) Patent Application Publication
(10) Pub. No.: US 2008/0186466 A1
(43) Pub. Date: Aug. 7, 2008

(54) ELEMENT FOR DEFOCUSING TM MODE FOR LITHOGRAPHY

(76) Inventors: Gabriel Y. Sirat, Rehovot (IL); Joseph Fisher, Jerusalem (IL)

Correspondence Address: FOLEY & LARDNER LLP, 777 EAST WISCONSIN AVENUE, MILWAUKEE, WI, 53202-5306, US

(21) Appl. No.: 11/946,730

(22) Filed: Nov. 28, 2007

Related U.S. Application Data
(63) Continuation-in-part of application No. 29/246,435, filed on Apr. 12, 2006, now abandoned.
(60) Provisional application No. 60/924,075, filed on Apr. 30, 2007.
(60) Provisional application No. 60/670,272, filed on Apr. 12, 2005.

(51) Int. Cl. G03F 7/20; G03F 7/26; G03F 7/207

(52) U.S. Cl. 355/55; 355/77; 355/67

(57) ABSTRACT

A method for imaging a mask pattern with small features through a lithographic system includes an illumination source and providing a uniaxial material having an ordinary index of refraction and a different extraordinary index of refraction. The extraordinary mode is modified such that the extraordinary mode is defocused relative to the ordinary mode. Light from the illumination source is passed through the material and focusing the ordinary mode on an image plane and defocusing the extraordinary mode relative to the image plane.

### CROSS-REFERENCE TO RELATED PATENT APPLICATIONS

This application claims priority to provisional application No. 60/924,075 titled “Optical Element Made from a Uniaxial Material, Optical Method, Optical Configuration and Optical System for Immersion Lithography” filed Apr. 30, 2007 and to U.S. application Ser. No. 29/246,435 entitled “Multifield incoherent Lithography, Nomarski Lithography and multifield incoherent Imaging” filed Apr. 12, 2006 which claimed priority to provisional application No. 60/670,272 entitled “Nomarski lithography: A New Approach to SubWavelength Lithography” filed Apr. 12, 2005 and a provisional application entitled “Nomarski lithography: A New Approach to SubWavelength Lithography, Second part: Resolution tripling, longitudinally displaced Nomarski Lithography and Conoscopic Lithography” filed Sep. 2, 2005, all of which are incorporated by reference in their entirety.

### BACKGROUND OF THE INVENTION

The present invention relates to lithography projection objectives and to the optical material used as the last optical element (LOE) in lithography. The present invention also relates to a projection objective for imaging a pattern provided in an object plane of the projection objective onto an image plane of the projection objective (in the following, in short, projection objective). The projection objective may be used, for example, for microlithographic projection exposure machines. This invention also relates to the use of birefringent plates and lenses to defocus the spurious TM mode in a projection objective. This invention also relates to an LOE and its constituent material. This invention relates also to flare, flare non uniformity and its compensation.

Immersion lithography is a photolithography technique that improves the resolution at the image plane by replacing the conventional air gap between the final lens and the wafer surface with a liquid medium that has a refractive index greater than one. The increase of resolution at the image plane is directly proportional to the index of refraction of the liquid.

A major issue in optical lithography is the transition of optical lithography from unpolarized to polarized imaging. This transition had been made necessary by the poor contrast of the TM mode at high angles of incidence, which, in higher incidence angles creates zero contrast or even contrast reversal. In polarized imaging optical systems, as are common for current lithographic systems, the system makes use of a single polarization, the preferred polarization; the second polarization, the unwanted polarization, is removed by a suitable polarization element. The amount of unwanted polarization is characterized by RPS, by the ratio of the intensity, by specific polarization or by ISP, total intensity in the preferred state.

First generation immersion lithography systems use water (n=1.44) as the immersion liquid and fused silica or calcium fluoride as the optical material of the LOE. These systems fulfill lithographic requirements for the 45 nm node. Second and third generation immersion lithography systems have been proposed to satisfy the lithographic requirements for the 32 nm and 22 nm nodes. One requirement of such systems is that the LOE have an index of refraction greater than 1.8 at a wavelength of 193 nm. The optical material of the LOE must comply with stringent optical quality requirements defined by an expert committee in Burnett's report, “High-index optical materials for 193-nm immersion lithography”, in Optical Microlithography XIX, edited by Donis G. Flagello, Proc. of SPIE Vol. 6154 (2006), presented at the SPIE meeting in February 2006, at San Jose and published in the proceedings of this meeting by the SPIE. The Burnett report requirements include optical isotropy, a band gap higher than the photon energy corresponding to a wavelength of 193 nm (6.41 eV), an intrinsic birefringence less than 10 nm/cm, an absorption coefficient, A₁₀, at 193 nm less than 0.01 cm⁻¹, and a stress-induced birefringence and homegeneity of the index of refraction of less than 1 nm/cm. Additionally, the material of the LOE must be capable of being commercially manufactured in significant sizes (i.e., several centimeters in thickness and diameter) and in the quantities needed.

Presently, no suitable material has been identified to closely meet the optical quality requirements for an LOE for second and third generation immersion lithography. Although two materials, ceramic spinel and lutetium aluminum garnet (LuAG), have been identified as possible candidates, both require years of research to approximate the stringent requirements.

Due to the requirement of optical isotropy, birefringent materials have been eliminated as potential candidates. Uniaxial, birefringent materials including sapphire were also removed as potential candidates despite having both a high index of refraction and low absorption coefficients in the ultraviolet (UV).

The industry wide consensus, in 2006, indicated the inability to use birefringent materials as the last optical element. as expressed in Burnett's report: “The optical requirements for a high-index final lens element for a 193 nm immersion system defined our search. First, the material would have to have highly isotropic optical properties, thus either have cubic crystal structure or be amorphous or polycrystalline. This eliminated a substantial fraction of high-index UV materials such as sapphire, which is uniaxial.”

An additional parameter relevant to the imaging quality of a lithographic system is flare. Flare, unwanted scattered light arriving at the wafer, is created by the superposition of spurious reflections and diffusions in the optical system. The flare degrades the image quality and process window. The non-uniformity of flare impacts lithographic performances as CD control creating variations in these parameters.

Finally, a new technique, Double patterning, or, more generally, multiple patterning, is a class of technologies developed for photolithography to enhance the feature density. The four most common types are: double exposure, spacer mask, heterogeneous mask, and intermediate pattern accumulation.

### SUMMARY OF THE INVENTION

One embodiment of the invention relates to a method for imaging a mask pattern with small features through a lithographic system. An illumination source is provided and a uniaxial material is provided having an ordinary index of refraction and a different extraordinary index of refraction. The extraordinary mode is modified such that the extraordinary mode is defocused relative to the ordinary mode. Light from the illumination source is passed through the material and the ordinary mode is focused on an image plane and defocusing the extraordinary mode relative to the image plane.

In a further aspect of the invention a photoresist is provided in the image plane and photoresist is imaged with the ordinary mode.

In a further aspect of the invention, the uniaxial material is made of one of Sapphire, MgF2, KD*P, quartz or BBO.

In a still further aspect of the invention, the material is in the form of a planar plate member.

In yet a further aspect of the invention a mask is adjacent the uniaxial birefringent plate member and the plate is positioned between the mask and the photoresist.

In a still further aspect of the invention the uniaxial birefringent plate is the substrate material of the mask.

In yet another aspect of the invention, the light is passed through a uniaxial birefringent last optical element.

In another aspect of the invention, the last optical element is a plano-convex lens.

In a still further aspect of the invention the method described herein is utilized for fabricating a semiconductor device.

In a further aspect of the invention the uniaxial material is one of a plate, wedge or lens, wherein the material includes a last optical module having a plurality of elements, all the elements being made of the same uniaxial crystal. The first element of the last optical module is made of a uniaxial crystal with the optical axis of the crystal being aligned parallel to the optical axis of the optical system, a surface between the first and a second element carrying no optical power. The second element is made of the same uniaxial material as the first element with the crystal optical axis being inclined below 6 degrees relative to the optical axis. The crystal optical axis angle relative to the optical axis of the system and the surface shape of the second element is configured to reduce flare and flare non-uniformity on the image on the photoresist by adding additional flare to the image at positions with lower flare content.

In another embodiment of the invention a lithographic system for imaging a mask pattern with small features through a lithographic system includes an illumination source and a uniaxial material having an ordinary index of refraction and a different extraordinary index of refraction. The material is configured to focus the ordinary mode on an image plane and to modify the extraordinary mode such that the extraordinary mode is defocused relative to the ordinary mode. A photoresist is positioned at an image plane, and the ordinary mode from the illumination source is focused on the image plane and the extraordinary mode is defocused relative to the image plane.

In another embodiment, a lithographic system includes a projection objective for imaging a pattern provided in an object plane of the projection objective onto an image plane of the projection objective suitable for microlithography projection exposure machines includes a UV light source providing light and a polarization controller to control the polarization of the light. An optical module is included to shape the spatial profile of the light. A mask is included to define a pattern. Optical elements including a last optical element is placed along a geometric axis and a wafer and a photoresist coated on the wafer is placed such that the photoresist is positioned at the image plane of the projection objective. An immersion liquid is filled in between the last optical element and the wafer. The last optical element is in the form of a plano-convex lens, with the flat surface oriented facing the wafer and up against the immersion liquid. The material of the last optical element is made of uniaxial crystal, and the optical axis of the uniaxial crystal is perpendicular to the bottom surface of the last optical element. The image is created in the wafer in a preferred polarization, by the projection objective, wherein unwanted polarization creates a uniform background in the photoresist.

In yet another embodiment, A method of immersion lithography includes providing a UV light source providing light; and providing a polarization controller to control the polarization of the light. An optical module is provided to shape the spatial profile of the light. A mask is provided to define a pattern. Optical elements are provided including a last optical element placed along a geometric axis. A wafer and a photoresist coated on the wafer is placed such that the photoresist is positioned at the image plane of the projection objective. An immersion liquid is filled between the last optical element and the wafer. The last optical element is in the form of a plano-convex lens, with the flat surface oriented facing the wafer and up against the immersion liquid, wherein the material of the last optical element is made of uniaxial crystal, and the optical axis of the uniaxial crystal is perpendicular to the bottom surface of the last optical element and creating an image on the wafer in a preferred polarization and creating a uniform background in the photoresist from the unwanted polarization.

In still another embodiment a projection objective for imaging a pattern provided in an object plane of the projection objective onto an image plane of the projection objective suitable for microlithography projection exposure machines includes a UV light source providing light, a polarization controller to control the polarization of the light; an optical module to shape the spatial profile of the light, a mask to define a pattern; optical elements including a last optical element placed along a geometric axis; a wafer and a photoresist coated on the wafer placed such that the photoresist is positioned at the image plane of the projection objective. The photoresist is kept at a distance from the last optical element to neutralize the decay of high frequency spatial components due to non propagating waves. The last optical element is in the form of a plano-convex lens, with the flat surface oriented facing the wafer. The material of the last optical element is made of uniaxial crystal and the optical axis of the uniaxial crystal is perpendicular to the bottom surface of the last optical element. An image is created in the wafer in a preferred polarization, by the projection objective, wherein unwanted polarization creates a uniform background in the photoresist.

### BRIEF DESCRIPTION OF THE DRAWINGS

FIG. 1 illustrates an immersion lithography system including a birefringent uniaxial plate or lens according to an embodiment of the invention.

FIG. 2 illustrates a birefringent uniaxial plate or lens according to a further embodiment.

FIG. 3 illustrates a birefringent uniaxial plate merged with the mask substrate, according to another embodiment of the invention.

FIG. 4 illustrates a birefringent uniaxial last optical element for use in a lithographic system according to a further embodiment.

FIG. 5 illustrates an immersion lithography system including a birefringent uniaxial plate or lens at the mask position and a birefringent uniaxial last optical element according to a still further embodiment.

FIG. 6 illustrates a birefringent uniaxial plate with mask and a birefringent uniaxial last optical element according to a further embodiment.

FIG. 7 illustrates a birefringent uniaxial last optical element for use in a lithographic system, including non-uniformity flare control, according to a further embodiment.

### DETAILED DESCRIPTION OF THE PREFERRED EMBODIMENTS

In the ideal case, the image created at the photoresist by an immersion lithographic system includes substantially all of its energy in the TE mode with no energy in the TM mode, for the reasons described below. In a real system, even illuminated by a perfect TE mode illumination, several effects create birefringence effects which translate to a build-up of TM energy; these effects include the pattern diffraction effects, localized polarization errors due to sub-wavelength features, stress birefringence in the mask substrate, residual birefringences in the optical element and stress and temperature effects in the LOE and the liquid. As is known in the art in the uniaxial crystal the TM Mode is known as the extraordinary mode and the TE Mode is known as the ordinary mode. Both the term TE mode and ordinary mode are used interchangeably and the term TM mode and extraordinary mode are used interchangeably in this application. Further, the term preferred polarization in this application refers to the TE mode or ordinary mode and the term unwanted polarization refers to the TM mode or extraordinary mode. The benefit of defocusing of the light in the TM Mode is explained by review in a following paragraph of the following standard equations in an immersion lithographic system.

Due to the property of birefringences to add as quadric these birefringences amplifies one another and the overall TM energy is higher then the amount created by each one of the effects separately.

One of the main challenges facing the design of masks for third generation immersion lithography is the effect of localized polarization errors in the mask itself. These effects are strongly enhanced for higher resolution. Furthermore, these effects are concentrated in small geometries of the order of the design rules. These geometries include edges, corners, transitions and any pattern containing larger amount of high spatial frequency components. In these geometric positions, the additional polarization errors compound the already large complexity due to their specific spatial behavior. By defocusing the TM mode, and averaging this additional polarization content on a large area, this embodiment markedly simplifies the complexity of mask design in second and third generation lithography.

A crude approximation is that the overall surface of the small geometries of the order of the resolution is 5-10% of the surface. It is possible, to increase the tolerance on the TM contents at these points by a factor of 5 while decreasing by only 20% the tolerance of the quiet surfaces, without altering the overall quality. Even with a larger area of small geometries of the order of the resolution an important improvement can be realized. Any angle between the optical axis of the crystal and the chief ray will create additional flare. The flare is proportional to the sin² A, where A is the angle between the crystal optical axis and the chief ray. In a preferred emobidment angle A is 5 degrees or less.

Additionally, a major issue in mask quality is the presence of stress birefringence in the mask substrate. The tight tolerances in the mask substrate translate to very high cost of the mask itself.

The solution presented in several embodiments of this invention is the defocusing of the TM mode at one or more positions along the optical path. Defocusing of the TM mode supplement the traditional way or reducing the TM amount by illumination control, by decorrelating the different birefringence terms. Additionally it reduces the influence of the TM energy by removing the modulation term as explained below.

In contrast to the industry wide consensus, the present inventors has recognized that uniaxial materials, such as sapphire, can indeed be used as plates and lenses in a immersion lithographic system, as long as certain conditions of the system exist. The conditions have to imply that the TE mode will propagate indistinguishably from its propagation in an isotropic material and that the TM mode will be strongly defocused. These conditions include telecentricity, which is provided in lithographic systems at the object and image plane. Additionally these conditions include that the surface facing the object or image plane—which one being applicable—be planar and that the optical axis of the crystal being perpendicular to this surface.

This invention introduces a paradigm shift; viewing the birefringence of uniaxial crystals as an enabler and as a direct consequence of polarized imaging. A system including birefringent plates and lenses will perform much better than a system including only optical elements made of isotropic material. This invention demonstrates that despite previous belief, the strong birefringence of the uniaxial crystal material improves the performances of the system.

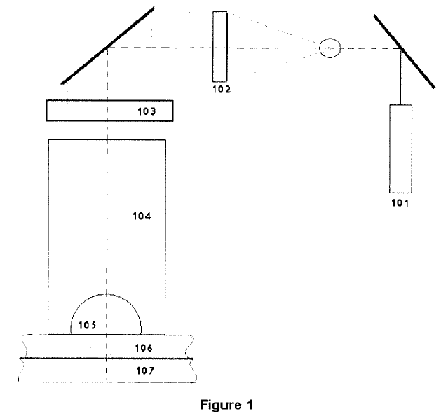

In the first embodiment, FIG. 1, an immersion lithographic system includes a plate or lens made of uniaxial crystal that is placed after the mask. This embodiment creates a low amount of TM mode, and a high imaging contrast. Unlike prior art this embodiment solves the problem of the TM mode in a practical way by providing additional means to reduce the amount of TM mode and/or its influence in localized features. The plate can be made from any suitable uniaxial material, as MgF₂, quartz, KD*P, or sapphire and does not require a high index of refraction. This embodiment is valid for a last optical element made of uniaxial material, as sapphire, and also for a last optical element made of isotropic material as LuAG, and introduces the benefits of defocusing of the TM mode even for an isotropic LOE.

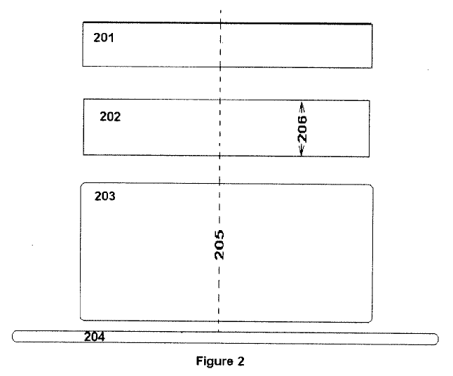

Referring to FIG. 2 a birefringent plate 202 having different indices of refraction for the TE and TM modes is positioned between the mask, 201, and the optical system 203, as the first optical element, or in any intermediate imaging plane provided that the image is telecentric. The wafer 204, and the optical axis of the system 205, are also represented. This embodiment creates a low amount of TM mode, and a high imaging contrast of all solutions. This embodiment is valid also for a last optical element made of isotropic material as LuAG, and introduces the benefits of defocusing of the TM mode even for an isotropic LOE.

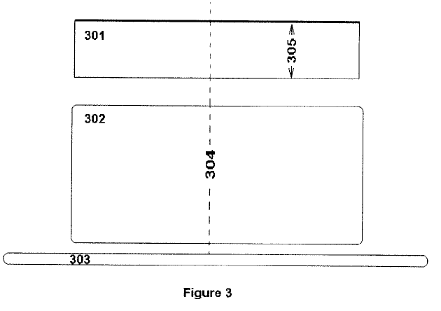

Referring to FIG. 3 in a second embodiment, a birefringent plate 305, with different indices of refraction for the TE and TM modes is positioned between the mask, 301, and the optical system 302, as the first optical element, or in any intermediate imaging plane provided that the image is telecentric. The plate of the previous embodiment has been merged with the mask substrate. The mask is inverted relative to the conventional system with the substrate/uniaxial plate being impacted by the light after passing through the mask pattern. This embodiment removes the stress birefringence of the substrate—a major contributor to the TM energy. This embodiment creates the lowest amount of TM mode, and the highest imaging contrast of all solutions, but necessitates additional engineering. The wafer 303, and the optical axis of the system 304, is also represented. This embodiment is valid also for a last optical element made of isotropic material as LuAG, and introduces the benefits of defocusing of the TM mode even for an isotropic LOE.

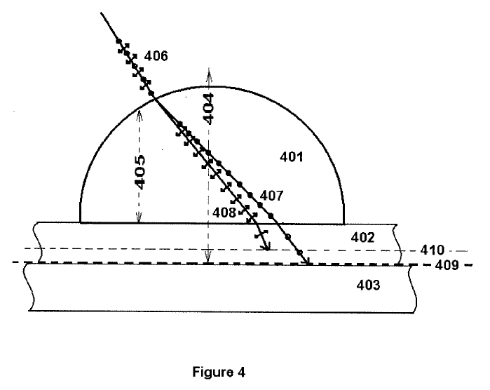

The TM defocusing can also be realized at the LOE as described in FIG. 4. An incoming ray 406, containing TE and TM components, is refracted by the last optical element 401. The TE and TM components are superimposed spatially up to the first surface of the last optical element 401. The TE mode is refracted as 407, and is focused at plane 409, at the photoresist. The TM mode 408, is refracted differently, and is focused at plane 410, the extraordinary focus. A liquid 402 and the wafer 403, are also represented. The optical axis of the system 404, parallel to all chief rays, in the case of a telecentric system, and the crystal optical axis 405, is also represented. Additionally this embodiment solves the problem of the material of the last optical element, which can be made of sapphire, a readily available material. Unlike prior art it solve it in a practical way by providing additional means to reduce the amount of TM mode and/or its influence.

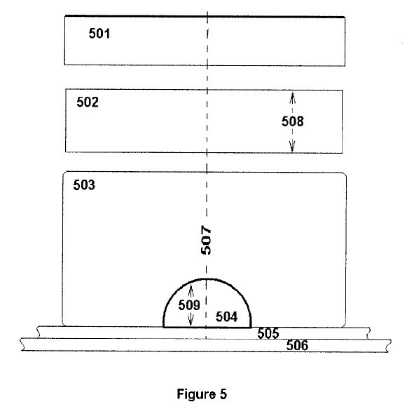

FIG. 5 illustrates an immersion lithography apparatus according to one embodiment of the invention. The mask is represented as 501. The uniaxial plate—or lens—at the first element is represented as 502. The plurality of optical elements 503 represent the portion of the immersion lithography system comprising optical elements providing telecentric propagation of light from a light source (not shown) to the LOE 504. The plurality of optical elements 503 may include lenses, mirrors, or a holographic optical elements. The LOE 504 comprises a uniaxial, birefringent material. The LOE 504 may comprise sapphire, for example, or other uniaxial materials with high index of refraction in single crystal form. The LOE 504 may be a plano-convex lens with a flat surface as the last surface toward the object to be imaged. The LOE 504 is aligned with its optical axis, 509, perpendicular to the lens flat surface. An immersion liquid 505 is placed between the flat surface of the LOE 504 and the wafer 506. The wafer 506 comprises a layer of photoresist on its surface that is irradiated by light. Also shown in FIG. 5 is the direction of the optical axis 507 of the optical system.

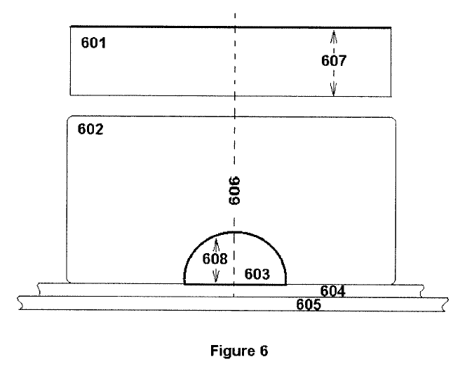

FIG. 6 illustrates an immersion lithography apparatus according to one embodiment of the invention. This embodiment differs from the previous one by the merging of the uniaxial plate with the mask substrate 601, in a way similar to a previous embodiment. The plurality of optical elements 602 represent the portion of the immersion lithography system comprising optical elements providing telecentric propagation of light from a light source (not shown) to the LOE 603. The plurality of optical elements 602 may include lenses, mirrors, or a holographic optical elements. The LOE 603 comprises a uniaxial, birefringent material. The LOE 603 may comprise sapphire, for example, or other uniaxial materials with high index, in single crystal form. The LOE 603 may be a plano-convex lens with a flat surface as the last surface toward the object to be imaged. The LOE 603 is aligned with its optical axis 608, perpendicular to the lens flat surface. An immersion liquid 604 is placed between the flat surface of the LOE 603 and the wafer 605. The wafer 605 comprises a layer of photoresist on its surface that is irradiated by light. Also shown in FIG. 6 is the direction of the optical axis 606 of the optical system.

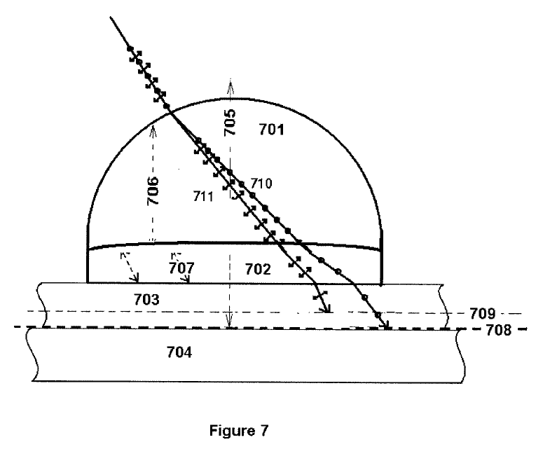

FIG. 7 represents an additional embodiment, similar to the embodiment described in FIG. 4, with the additional functionality of flare uniformization. An incoming ray 406, containing TE and TM components, is refracted by the first crystalline element 701. The TE and TM components are superimposed spatially up to the first surface of the element before the first crystalline element 701. The TE mode is refracted as 710, and is focused at plane 708, at the photoresist. The TM mode 711, is refracted differently, and is focused at plane 709, the extraordinary focus. A liquid 703 and the wafer 704, are also represented. The optical axis of the system 705, parallel to all chief rays, in the case of a telecentric system, and the crystal optical axis, of the first crystalline element 706, are also represented. A single element 702,—or several—additional element(s), is made from the same crystalline material are also present. This element(s) can be made of plate or lenses—provided that the intermediate surfaces have no optical power in the sense of geometrical optics. The optical axis of the last element 707, is tilted—slightly—relative to the axis of the first crystalline element. The form of the last crystalline element(s) 702, and the direction of its optical axis 707, does not impact the geometrical performances of the system. However, they impact the flare of the system. By a proper optimization procedure, the shape and axes can be chosen to reduce the flare non-uniformity, even if it creates a small amount of additional flare. Additionally this embodiment solves the problem of the material of the last optical element, which can be made of sapphire, a readily available material. Unlike prior art it solve it in a practical way by providing additional means to reduce the amount of TM mode and/or its influence.

In several embodiments a polarized light in the TE mode is directed through the LOE represented in FIG. 4 by 401, in FIG. 5 by 504, in FIG. 6 by 603, and in FIG. 7 by 701 and 702. Light rays, in TE mode, enter the LOE at any angle and are refracted in the ordinary mode through the LOE. Light rays, in TM mode, enter the LOE at any angle and are refracted in the extraordinary mode through the LOE. The light ray exits the LOE at the flat surface and travels through the liquid (402, 505 and 604) in the TE mode and finally forms an image on photoresist (403, 506 and 605).

In several embodiment a polarized light in the TE mode is directed through the uniaxial plate (or lens) represented in FIG. 1 by 103, in FIG. 2 by 201, in FIG. 3 by 301, in FIG. 5 by 502, and in FIG. 6 by 601. Light rays, in TE mode, enter the uniaxial plate (or lens) at any angle and are refracted in the ordinary mode through the LOE. Light rays, in TM mode, enter the uniaxial plate (or lens) at any angle and are refracted in the extraordinary mode through the uniaxial plate.

In a preferred embodiment the LOE 401, 504, 603, 701 and 702 and the first optical elements 103, 201, 502, 601 are formed from sapphire. Sapphire is a uniaxial crystal that is well developed and with a high index of refraction and low absorption coefficient in the ultraviolet (UV) range of the electromagnetic spectrum including the deep ultraviolet (DUV), such as at wavelengths of about 193 nm. When used in the various embodiments described above, sapphire is indistinguishable from optically isotropic materials and exceeds the stringent optical quality requirements defined by the Burnett et al. committee for second and third generation immersion lithography systems.

In a preferred embodiment the first optical elements 103, 201, 502, 601 are formed from MgF₂, quartz, KD*P or BBO. All these materials are uniaxial crystals that are well developed and with low absorption coefficient in the ultraviolet (UV) range of the electromagnetic spectrum including the deep ultraviolet (DUV), such as at wavelengths of about 193 nm. When used in the various embodiments described above, an optical plate made of these materials is indistinguishable from optically isotropic materials and exceeds the stringent optical quality requirements defined by the Burnett et al. committee for second and third generation immersion lithography systems.

Sapphire is a well-known, prevalent material in the optical industry. Technologies for crystal growing, orienting, cutting, polishing—including Magneto Rheological Finishing (MRF)—and coatings have been utilized for decades, are well-mastered, and are commercially available from several sources.

The absorption coefficient of commercial, off-the-shelf sapphire, represented as A₁₀, is the range of 0.11-to 0.3 and does not meet the requirements (0.02-0.03 for use as the uniaxial crystal LOE, and necessitates additional development for some applications. The best value of off-the-shelf material has an absorption (A₁₀) in the range of 0.11-0.2; values in the range of 0.12-0.14 have also been published for crystals, specially those that are annealed. These values are based on published measurements on a commercial sample of Helmex Ultra from Crystal Technologies. Apparently, the absorption of Sapphire at 193 nm is primarily due to F-centers, and may be improved further by annealing.

In LuAG, the actualized target value of the absorption factor A₁₀, is 0.003-0.005, although in some systems the absorption may be as high as 0.01. The target value of the sapphire absorption coefficient can be much higher because of its superior thermal conductivity and the possibility to use a thinner element, due to the higher mechanical strength of Sapphire. A comparison between the two materials shows that sapphire's thermal conductivity is nearly five times higher than in LuAG, while the temperature dependence of the index of refraction is slightly lower in sapphire compared to LuAG (based on Thomas model and not on measured data).

Based on preliminary evaluations, based on the ratio of thermal conductivity and of the temperature variation of the refractive index, in LuAG and sapphire, a target value of 0.02-0.03 for the absorption (A₁₀) of sapphire is desired. It is noted that sapphire is one of the constituents of LuAG and the huge investment in raw materials quality and crucibles done for LuAG is also beneficial for sapphire.

In any real system, a small amount of energy leaks due to tolerances in the system resulting in additional unwanted polarization—TM polarization in this case. The amount of unwanted polarization is characterized by total intensity in the preferred state (IPS), or by the ratio of the intensity by specific polarization (RSP). The TM polarization, propagating in the extraordinary mode, does not focus, and is transformed in uniform light with a scale of the order of a few hundredths of microns to 1 mm. The advantage of this functionality will be discussed below.

One aspect of the invention concerns optimizing a birefringent projection objective lens differently for the TE mode, the preferred polarization, and the TM mode, the unwanted polarization. The standard equations for immersion lithographic system are shown in equations (1) through (4) below. In equation (1), the final image is composed of the sum of three components: the TE image that is the preferred polarization; the TM image that is the unwanted polarization; and flare

I_{TOT}=I_{TE}+I_{TM}+I_{FLARE} (1)

To analyze the TE and TM image, classical analysis of coherent two-wave imaging is used. Equation (1) approximates illumination and very small partial coherence for alternating phase shifting masks. The amplitudes of the two beams are represented by A₁ and A₋₁, with adequate subscripts of TE and TM, respectively. The angle between A₁ and A₋₁ is θ.

Equations (2) and (3) represent the TE image and the TM image, respectively. λ is the wavelength, k is the wavevector=2π/λ, x is the lateral position.

I_{TE}=I_{TE}^{DC}+I_{TE}^{MOD}=(|A|_{TE1}²+|A|_{TE-1}²)+2A_{TE1}A_{TE-1} cos(2k×sin(θ)) (2)

I_{TM}=I′_{TM}^{DC}+I′_{TM}^{MOD}=<A_{TM1}²+A_{TM-1}²> (3)

I_{TE}^{DC} and I_{TE}^{MOD} are the bias and modulation terms of the TE polarization; I_{TM}^{DC} and I_{TM}^{MOD} are the bias and modulation terms of the TM polarization; I_{FLARE} is the bias due to flare.

The final image is composed of the sum of five components:
The constant term of TE mode
The interference term of the TE mode
The constant term of TM mode
The interference term of the TM mode
Additional flare

The contrast of the image is defined in equation (4) as:

$$Contr = \frac{{I}_{TE}^{MOD} + {I}_{TM}^{MOD}}{{I}_{TE}^{DC} + {I}_{TM}^{DC} + {I}_{FLARE}} \qquad ( 4 )$$

Three of the components, I_{TE}^{DC}, I_{TM}^{DC} and I_{FLARE} create bias and need to be minimized. The I_{TE}^{MOD} contains information and is the signal term. The last term, I_{TM}^{MOD} was also a signal term for previous generations of lithographic equipment, when θ was small, but had evolved to be a spurious term in new generations of lithographic equipment, due to its additional cos(2θ) dependence.

The interference term of the TM mode depends on the incidence angle. When θ is at an angle of 45°, the interference term is 0. The θ angle of 45° correspond to a numerical aperture (NA) of 1.2, for a photoresist of index of refraction of 1.7. Above this value θ the interference term is negative and reduces the image contrast. This general description is valid for any illumination, mask, polarization state or imaging system.

In modern lithographic systems where the numerical aperture is above 1.5, θ is greater to or substantially equal to 45 degrees.

The way to deal with the TM polarized mode, in existing systems, is to reduce the amount of TM mode energy by a careful design of the illumination, the mask, and the optical system. Indeed, introduction of polarization control improved the resolution by 20% in previous lithographic generations and polarization control is indispensable in new generations of lithography. However, this solution had reached its limit.

The solution described in this embodiment is to defocus the TM mode. The intensity of the TM mode, for defocusing is given by:

I_{TM}=I′_{TM}^{DC}+I′_{TM}^{MOD}=<A_{TM1}²+A_{TM-1}²> (5)

with I′_{TM}^{DC}, being the constant term of TM mode for defocused TM. I′_{TM}^{MOD} is the interference term of the defocused TM mode and is equal to zero. A_{TM1} and A_{TM-1} have the same definition as in the previous equations (1) and (2).

The intensity of the TM mode, for defocusing does not include an interference term. The interference term is 0 because the average of the modulation terms is 0.

The properties of the uniaxial first and last optical element much simplify this task by removing the most problematic of the mechanisms of the creation of the unwanted polarization, namely the depolarization due to sub-assist patterns and small sub-wavelength features. The reason is that by defocusing any image point on a spot with a very large diameter this effect is averaged out and reduced by a factor proportional to the ratio of surfaces instead of being concentrated on a single point.

The approach taken herein totally differs from previous ideas based on compensation of the birefringence, which have not been implemented industrially. This system pushes the new paradigm of polarized imaging to its extreme by designing a priori an optical system able to carry only the preferred polarization.

In essence, the uniaxial crystal in first and last optical element in the ordinary mode, is “birefringence free.” Light propagating in the ordinary mode in a uniaxial crystal, beyond the crystal's optical axis, is unperturbed by spurious birefringence or optical activity. Spurious birefringence damping by natural birefringence is based on the principle of quadratic addition of birefringence. As a result, the uniaxial crystal in first and last optical element is independent of stress and thermal-induced birefringence. It is an important issue for the last optical element, in which strong temperature gradients may develop. It is also an important issue for the uniaxial plate (or lens) due to the stress birefringence existing in mask substrates.

FIG. 1 illustrates an optical system for immersion lithography which includes a uniaxial birefringent plate according to the first embodiment of the invention. The optical system is a projection objective for imaging a pattern provided in an object plane of the projection objective onto an image plane of the projection objective suitable for microlithography projection exposure machines. The system of FIG. 1 includes an illumination source 101, which may be a laser, for example, and/or a UV light source. The light, polarized by a polarization system and shaped by a shaping optical system (not shown) is projected onto the mask 101, which is defines a pattern to be imaged onto a photoresist coated on a wafer 107. The light from the mask passes through the uniaxial plate 103. It is directed to optical elements 104, which includes an last optical element 105. The wafer 107 is disposed after the last optical element 105. An immersion liquid 106 is filled in between the last optical element and the wafer 107. The optical elements 104 provide telecentricity, in object and image planes, for all points across an object imaged by the system in the photoresist 107. The last optical element is in the form of a plano-convex lens, with the flat surface oriented facing the wafer 107 and up against the immersion liquid 106. The material of the last optical element 105 is made of uniaxial crystal, in one embodiment and of isotropic material in another one. In the case that the last optical element, 105, is made of uniaxial crystal, its optical axis is perpendicular to the bottom surface of the last optical element 105. Thus, an image is created in the wafer 107 in a preferred polarization, by the projection objective, wherein the energy and the localized features of the spurious image created in the wafer 107 in an undesired polarization is minimized.

To implement birefringent projection objective design, a uniaxial first and last optical element is proposed in one embodiment. This concept can be implemented using other means. One embodiment utilizes assemblies of polarizing beamsplitters.

Where a primary application of this invention is for immersion lithography in the DUV range, such as 193 nm, for example, using liquids, the same application can be used in solid immersion lithography.

The way to channel the preferred polarization into the ordinary mode of the crystal for a desired image will now be addressed. The preferred polarization comprises the TE mode. The TE mode and the ordinary mode are both transverse modes. It is possible to make the TE mode and the ordinary mode coincide under special conditions, described below.

The definition of a few terms will be helpful in this discussion. A Snell plane for a particular light ray is a plane that contains both the light ray and the ray after it is refracted by a planar optical media.

The Snell plane and ordinary plane can be made coincident for an arbitrary ray, under certain conditions. Under this assumption, any ray of any point propagating in the TE mode into the photoresist, will propagate in the crystal in the ordinary mode, effectively channeling the image in the preferred polarization into the ordinary mode. As a result a single image is projected onto the photoresist.

In one embodiment a single image is projected onto the photoresist through a uniaxial crystal first and last optical element by employing the following conditions: 1) The incoming light is polarized in the TE mode prior to propagating through the crystal. 2) The optical system has to be telecentric. 3) The bottom surface of the last optical element is planar. 4) The crystal optical axis is perpendicular to the bottom surface of the last optical element. It should be noted that a slight deviation from the these conditions may be tolerated in a practical system where a small amount of second image will not effect the performance of the process.

The use of immersion lithography in conjunction with other techniques, such as for example but not limited to, double patterning, an application of lithography in which two complementary patterns are imaged and/or etched sequentially on the wafer, is possible. This application refers to the immersion lithography part of any system using it without consideration of the other components of the lithographic solution.

A birefringent optical element can also be used in other applications. These applications are characterized by the fact that the use of birefringent materials as replacement of isotropic materials improves the system performances and/or parameters. It is also noted that the restriction to a single polarization is acceptable in the applications. Examples of such applications may potentially be found in Terahertz imaging, for high power laser focusing, or in certain cases of imaging.

It is important to note that the method and construction of the lithographic systems described here are illustrative only. While the present invention has been described in connection with a number of embodiments and implementations, the present invention is not so limited but covers all such changes and modifications as fall within the invention as defined by the appended claims. For example the features described herein may be combined together collectively or individually or in any particular arrangement. Those skilled in the art who review this disclosure will readily appreciate that many modifications are possible (e.g., variations in sizes, dimensions, structures, shapes, and proportions of various elements, values of parameters, use of materials, orientations etc.) without materially departing from the novel teachings and advantages of the subject matter recited in the claims. Accordingly, all such modifications are intended to be included within the scope of the present invention as defined in the appended claims. The order or sequence of any process or method steps may be varied or re-sequenced according to alternative embodiments. Other substitutions, modifications, changes and omissions may be made in the design, operating conditions and arrangement of the exemplary embodiments without departing from the scope of the present invention as expressed in the appended claims.

What is claimed is:

1. A method for imaging a mask pattern with small features through a lithographic system:
providing an illumination source;
providing a uniaxial material having an ordinary index of refraction and a different extraordinary index of refraction;
modifying the extraordinary mode such that the extraordinary mode is defocused relative to the ordinary mode;
passing light from the illumination source through the material and focusing the ordinary mode on an image plane and defocusing the extraordinary mode relative to the image plane.

2. The method of claim 1, further providing a photoresist in the image plane; and imaging the photoresist with the ordinary mode.

3. The method of claim 1, wherein the uniaxial material is made of one of Sapphire, MgF2, KD*P, quartz or BBO.

4. The method of claim 3, wherein the material is in the form of a planar plate member.

5. The method of claim 4, wherein a mask is adjacent the uniaxial birefringent plate member and positioned between the mask and the photoresist.

6. The method of claim 5, wherein the uniaxial birefringent plate is the substrate material of the mask.

7. The method of claim 5 or 6, further including passing the light through a uniaxial birefringent last optical element.

8. The method of claim 7, wherein the last optical element is a plano-convex lens.

9. The method of claim 1, utilized for fabricating a semiconductor device.

10. The method of claim 1, wherein the uniaxial material is at least one of a plate, wedge or lens.

11. The method of claim 1, wherein the material includes a last optical module having a plurality of elements, all the elements being made of the same uniaxial crystal;
wherein the first element of the last optical module is made of a uniaxial crystal with the optical axis of the crystal being aligned parallel to the optical axis of the optical system, a surface between the first and a second element carrying no optical power; and
the second element being made of the same uniaxial material as the first element with the crystal optical axis being inclined below 6 degrees relative to the optical axis;
wherein the crystal optical axis angle relative to the optical axis of the system and the surface shape of the second element being configured to reduce flare and flare non-uniformity on the image on the photoresist by adding additional flare to the image at positions with lower flare content.

12. A lithographic system for imaging a mask pattern with small features through a lithographic system:
an illumination source;
a uniaxial material having an ordinary index of refraction and a different extraordinary index of refraction, the material being configured to focus the ordinary mode on an image plane and to modify the extraordinary mode such that the extraordinary mode is defocused relative to the ordinary mode;
a photoresist positioned at an image plane, wherein the ordinary mode from the illumination source is focused on the image plane and the extraordinary mode is defocused relative to the image plane.

13. The lithographic system of claim 12, wherein the uniaxial material is formed from one of sapphire, MgF2, KD*P, quartz or BBO.

14. The lithographic system of claim 13, wherein the material is in the form of a planar plate member.

15. The lithographic system of claim 14, wherein a mask is adjacent the uniaxial birefringent plate member, the plate member being located between the mask and the photoresist.

16. The method of claim 15, wherein the uniaxial birefringent plate is the substrate material of the mask.

17. The lithographic system of claim 15 or 16, further including passing the light through a uniaxial birefringent last optical element.

18. The lithographic system of claim 17, wherein the last optical element is a plano-convex lens.

19. The lithographic system of claim 18 wherein,
the illumination source includes a UV light source providing light; and further including:
a polarization system to control the polarization of the light;
an optical module to shape the spatial profile of the light;
optical elements including the last optical element placed along a geometric axis;
a wafer coated with the photoresist and positioned such that the photoresist is in the image plane of the projection objective; and
wherein the photoresist is kept at a distance from the last optical element to neutralize the decay of high frequency spatial components due to non propagating waves,
wherein the last optical element is in the form of a plano-convex lens, with the flat surface oriented facing the wafer,
wherein the material of the last optical element is made of uniaxial crystal,
wherein the optical axis of the uniaxial crystal is perpendicular to the bottom surface of the last optical element,
wherein an image is created in the photoresist in a preferred polarization, by the projection objective, and
wherein the extraordinary mode creates a uniform background in the photoresist.

20. The method of claim 19, wherein the material is one of a plate, wedge or lens.

21. A semiconductor wafer processed using the apparatus of claim 19.

22. The apparatus of claim 19, wherein the optical elements provide telecentricity, within 5 degrees, for all points across an object imaged by the lithography apparatus.

23. The apparatus of claim 19, wherein the optical crystal axis is within 5 degrees from the perpendicular to the bottom plane of the last optical element.

24. A lithographic apparatus having a projection objective for imaging a pattern provided in an object plane of the projection objective onto an image plane of the projection objective suitable for microlithography projection exposure machines comprising:
a UV light source providing light;
a polarization controller to control the polarization of the light;
an optical module to shape the spatial profile of the light;
a mask to define a pattern;
optical elements including a last optical element placed along a geometric axis;
a wafer and a photoresist coated on the wafer placed such that the photoresist is positioned at the image plane of the projection objective; and
an immersion liquid filled in between the last optical element and the wafer, wherein the last optical element is in the form of a plano-convex lens, with the flat surface oriented facing the wafer and up against the immersion liquid,
wherein the material of the last optical element is made of uniaxial crystal,
wherein the optical axis of the uniaxial crystal is perpendicular to the bottom surface of the last optical element,
wherein an image is created in the wafer in a preferred polarization, by the projection objective,
wherein unwanted polarization creates a uniform background in the photoresist.

25. The apparatus of claim 24, wherein the optical elements provide telecentricity, within 5 degrees, for all points across an object imaged by the lithographic apparatus.

26. The apparatus of claim 24, wherein the optical crystal axis is within 5 degrees from the perpendicular to the bottom plane of the last optical element.

27. The apparatus of claim 24, wherein the last optical element comprises sapphire.

28. The apparatus of claim 24, wherein the last optical element comprises quartz.

29. The apparatus of claim 24, wherein the lithographic system uses double exposure and/or double patterning.

30. A method of immersion lithography comprising:
providing a UV light source providing light;
providing a polarization controller to control the polarization of the light;
providing an optical module to shape the spatial profile of the light;
providing a mask to define a pattern;
providing optical elements including a last optical element placed along a geometric axis;
a wafer and a photoresist coated on the wafer placed such that the photoresist is positioned at the image plane of the projection objective; and
filling an immersion liquid between the last optical element and the wafer;
wherein the last optical element is in the form of a plano-convex lens, with the flat surface oriented facing the wafer and up against the immersion liquid,
wherein the material of the last optical element is made of uniaxial crystal,
wherein the optical axis of the uniaxial crystal is perpendicular to the bottom surface of the last optical element;
creating an image on the wafer in a preferred polarization,
creating a uniform background in the photoresist from unwanted polarization.

31. The method of claim 30, wherein the optical elements provide telecentricity, within 5 degrees, for all points across an object imaged by the lithographic apparatus.

32. The method of claim 30, wherein the optical crystal axis is within 5 degrees from the perpendicular to the bottom plane of the last optical element.

33. The method of claim 30, wherein the last optical element comprises sapphire.

34. The method of claim 30, wherein the last optical element comprises quartz.

35. The method of claim 30, wherein the lithographic system uses double exposure and or double patterning.

36. A semiconductor wafer processed using the method of claim 30.

37. A projection objective for imaging a pattern provided in an object plane of the projection objective onto an image plane of the projection objective suitable for microlithography projection exposure machines, comprising:
a UV light source providing light;
a polarization controller to control the polarization of the light;
an optical module to shape the spatial profile of the light;
a mask to define a pattern;
optical elements including a last optical element placed along a geometric axis;
a wafer and a photoresist coated on the wafer placed such that the photoresist is positioned at the image plane of the projection objective; and
wherein the photoresist is kept at a distance from the last optical element to neutralize the decay of high frequency spatial components due to non propagating waves,
wherein the last optical element is in the form of a plano-convex lens, with the flat surface oriented facing the wafer,
wherein the material of the last optical element is made of uniaxial crystal,
wherein the optical axis of the uniaxial crystal is perpendicular to the bottom surface of the last optical element,
wherein an image is created in the wafer in a preferred polarization, by the projection objective,
wherein unwanted polarization creates a uniform background in the photoresist.
